(19) United States
(12) Patent Application Publication
(10) Pub. No.: US 2026/0123443 A1
(43) Pub. Date: Apr. 30, 2026

(54) PACKAGE STRUCTURE AND FABRICATION METHOD THEREOF

(71) Applicant: Taiwan Semiconductor Manufacturing Company, Ltd., Hsinchu (TW)

(72) Inventors: Li-Hsien Huang, Hsinchu County (TW); Huai-Ren Hu, Taichung City (TW); Guan Wei Chen, Taichung City (TW); Cian-Ming Huang, Hsinchu City (TW); Yu-Feng Huang, Hsinchu City (TW)

(73) Assignee: Taiwan Semiconductor Manufacturing Company, Ltd., Hsinchu (TW)

(21) Appl. No.: 18/929,654

(22) Filed: Oct. 29, 2024

(51) Int. Cl. H01L 23/544; H01L 23/00; H01L 23/31; H01L 25/00; H01L 25/10

(52) U.S. Cl. CPC H10W 46/00; H10W 90/00; H10W 70/09; H10W 70/60; H10W 72/01271; H10W 72/072; H10W 72/07211; H10W 72/07223; H10W 72/387; H10W 74/111; H10W 74/15; H10W 90/22; H10W 90/722; H10W 90/724; H10W 90/733; H10W 90/734

(57) ABSTRACT

A package structure includes a redistribution structure, a die and an underfill layer. The redistribution structure includes a first insulating layer, a second insulating layer, a first redistribution layer and a first alignment mark. The first redistribution layer and the first alignment mark are located between the first insulating layer and the second insulating layer. The die is attached to the redistribution structure. The second insulating layer includes a trench laterally located between the first alignment mark and the die. The underfill layer is located between the redistribution structure and the die. A portion of the underfill layer is filled in the trench.

### BACKGROUND

Generally, electronic devices such as smartphones and cameras contain various chips, each with different functions. As technology advances, to reduce the overall size of these devices, many manufacturers have attempted to integrate multiple dies into a single package. This approach not only minimizes the signal transmission paths between the dies but also contributes to the overall compactness of the device.

In the process of creating a package structure that includes multiple dies, the pick and place (PNP) process is commonly used to accurately position each die in its designated location. Alignment marks are typically employed during this process to ensure that the chips are placed precisely where intended. The accuracy of this placement is crucial for maintaining the performance and reliability of the final packaged device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view illustrating a package structure in accordance with some embodiments of the present disclosure.

FIG. 2A to FIG. 2P are cross-sectional views illustrating a fabrication method of the package structure in FIG. 1.

FIG. 3 is a cross-sectional view illustrating a package structure in accordance with some embodiments of the present disclosure.

FIG. 4 is a cross-sectional view illustrating a package structure in accordance with some embodiments of the present disclosure.

FIG. 5 is a perspective top view illustrating a package structure in accordance with some embodiments of the present disclosure.

FIG. 6A is a perspective top view illustrating a first alignment mark and a first trench in accordance with some embodiments of the present disclosure.

FIG. 6B is a perspective top view illustrating a second alignment mark and a second trench in accordance with some embodiments of the present disclosure.

FIG. 7 is a perspective top view illustrating a package structure in accordance with some embodiments of the present disclosure.

FIG. 8 is a flow chart of a fabrication method of the package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The package structure disclosed herein includes dies and a redistribution structure. In some embodiments of this disclosure, the dies are bonded to the redistribution structure using either soldering or eutectic bonding. Generally, the dies are first transferred to the bonding positions on the redistribution structure, and an alignment process is performed using alignment marks to ensure that the dies are properly positioned without any misalignment. Next, the contact points between the dies and the redistribution structure are heated, allowing the dies to bond securely to the redistribution structure.

In some embodiments of this disclosure, prior to transferring the dies to the redistribution structure, flux is applied to the bonding positions on the redistribution structure. This allows the dies, once transferred, to be temporarily held in place by the flux. Additionally, the flux helps to lower the temperature required for the subsequent heating process at the contact points. However, due to the fluidity of the flux, if the flux flows onto the alignment marks, the alignment marks may become obscured, reducing the accuracy of the alignment process and potentially preventing the dies from being correctly aligned. In some embodiments of this disclosure, trenches are provided around the alignment marks in the redistribution structure to accommodate the flux. This design prevents the flux from covering the alignment marks, thereby enhancing the precision of the alignment process and improving the yield of the package structure.

In some embodiments of this disclosure, the redistribution structure, which includes alignment marks and trenches designed to accommodate the flux, may be utilized in chip-on-wafer (CoW) technology, chip-on-wafer-on-substrate (CoWoS) technology, package-on-package (PoP) technology, wafer-on-wafer (WoW) technology, or other packaging technologies that involve flux-based bonding processes. In some embodiments of this disclosure, the aforementioned redistribution structure may be part of an interposer. The interposer is used to electrically connect the dies to the substrate and can facilitate signal exchange between multiple dies.

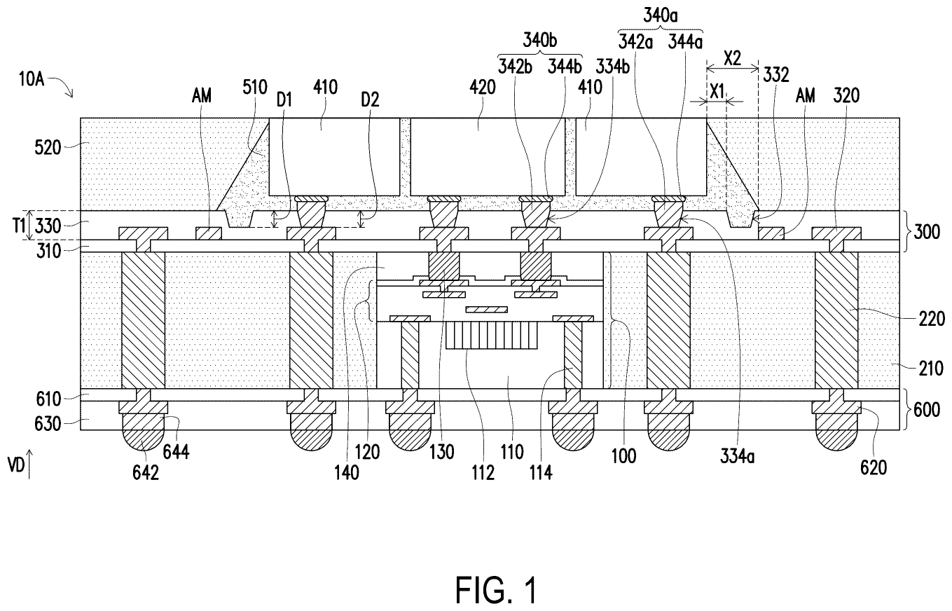

FIG. 1 is a cross-sectional view illustrating a package structure 10A in accordance with some embodiments of the present disclosure. Referring to FIG. 1, the package structure 10A includes an interconnect die 100, a first encapsulation layer 210, through insulator vias (TIVs) 220, a first redistribution structure 300, first semiconductor devices 410, a second semiconductor device 420, an underfill layer 510, a second encapsulation layer 520 and a second redistribution structure 600.

The interconnect die 100, for example, is a local silicon interconnect die (LSI). The interconnect die 100 includes a semiconductor substrate 110, an interconnect structure 120, conductive bumps 130, and a protective layer 140. The semiconductor substrate 110 contains integrated circuits 112 and through substrate vias (TSVs) 114. The interconnect structure 120 is located above the semiconductor substrate 110 and includes a plurality of metal interconnect layers and insulating layers that encapsulate these metal interconnects. The interconnect structure 120 is electrically connected to the integrated circuits 112 and the TSVs 114. The conductive bumps 130 are located above the interconnect structure 120. The protective layer 140 laterally surrounds the conductive bumps 130. In some embodiments, the protective layer 140 includes organic insulating materials (such as polyimide, epoxy resin, acrylic resin, phenol resin, benzocyclobutene (BCB), polybenzoxazole (PBO), or any other suitable poly-based dielectric material) or inorganic insulating materials.

The TIVs 220 are located around the interconnect die 100, and the first encapsulation layer 210 laterally encapsulates both the TIVs 220 and the interconnect die 100. The first encapsulation layer 210, for example, is a molding compound made of a polymeric material (such as epoxy resins, phenolic resins, silicon-containing resins, or other suitable resins), a dielectric material having low permittivity (Dk) and low loss tangent (Df) properties, or other suitable materials. In some embodiments, a dielectric material with low permittivity (Dk) and low loss tangent (Df) properties refers to a dielectric material with a Dk value less than or approximately equal to 4, and a Df value less than or approximately equal to 0.009. In some embodiments, the first encapsulation layer 210 may also include inorganic fillers or compounds (e.g., silica, clay, etc.) as additives to optimize its coefficient of thermal expansion (CTE).

The first redistribution structure 300 and the second redistribution structure 600 are located on the front and back sides of the first encapsulation layer 210, respectively. The TIVs 220 within the first encapsulation layer 210 electrically connect the first redistribution structure 300 to the second redistribution structure 600. In this embodiment, the interconnect die 100, the first encapsulation layer 210, and the TIVs 220 are situated between the first redistribution structure 300 and the second redistribution structure 600, but this disclosure is not limited thereto. In other embodiments, the first redistribution structure 300 and the second redistribution structure 600 are respectively disposed on opposite sides of a substrate core, which contains multiple TSVs extending from the first redistribution structure 300 to the second redistribution structure 600.

The first redistribution structure 300 includes a first insulating layer 310, a first redistribution layer 320, a second insulating layer 330 and alignment marks AM. The first insulating layer 310 is located above the interconnect die 100, the first encapsulation layer 210 and the TIVs 220. The first redistribution layer 320 and the alignment marks AM are located above the first insulating layer 310. The second insulating layer 330 is located above the first redistribution layer 320 and the alignment marks AM, and the first redistribution layer 320 and the alignment marks AM are located between the first insulating layer 310 and the second insulating layer 330. The number of redistribution layers and insulating layers in the first redistribution structure 300, as shown in FIG. 1, are not used to limit the scope of the present disclosure. In other embodiments, the first redistribution structure 300 may include additional redistribution layers and insulating layers as needed.

In some embodiments, the first redistribution layer 320 includes wiring portions located on the top surface of the first insulating layer 310 and via portions embedded within the first insulating layer 310. The via portions of the first redistribution layer 320 are connected with the TIVs 220 and the conductive bumps 130 of the interconnect die 100. Each of the alignment marks AM constitutes an independent structure and shall not be directly connected to any other conductive structures. The shape of the alignment marks AM may be adjusted according to specific requirements.

In some embodiments, the first redistribution layer 320 and the alignment marks AM are formed simultaneously. In some embodiments, the first redistribution layer 320 and the alignment marks AM each possess a single-layer or multi-layer structure, and the materials of the first redistribution layer 320 and the alignment marks AM comprise metal (such as aluminum, titanium, copper, nickel, tungsten, and/or alloys thereof) or other conductive materials.

The second insulating layer 330 includes trenches 332 (alternatively referred to as fiducial mark trenches), first via holes 334a and second via holes 334b. The first via holes 334a and the second via holes 334b are vertically overlapped with the first redistribution layer 320 along a vertical direction VD, whereas the trenches 332 are not vertically overlapped with either the first redistribution layer 320 or the alignment mark AM along the vertical direction VD. By ensuring that the trenches 332 do not overlap with the first redistribution layer 320, the risk of exposing the first redistribution layer 320 and causing short circuits is prevented.

In some embodiments, materials of the first insulating layer 310 and the second insulating layer 330 comprises organic insulating materials (such as polyimide, epoxy resin, acrylic resin, phenol resin, benzocyclobutene (BCB), polybenzoxazole (PBO), or any other suitable poly-based dielectric material) or inorganic insulating materials. In some embodiments, the thickness of the first insulating layer 310 is in a range between 4.9μm and 9.1 μm, while the thickness T1 of the second insulating layer 330 is in a range between 4.2 μm and 9.8 μm. In some embodiments, the first via holes 334a and second via holes 334b possess identical depths D2, whereas the depth D1 of the trenches 332 may be either equivalent to or different from the depth D2. In certain embodiments, both of the depth D1 and the depth D2 are less than the thickness T1 of the second insulating layer 330; however, the present disclosure is not limited thereto. In other embodiments, the depth D1 of the trenches 332 is approximately equal to the thickness T1 of the second insulating layer 330, causing the trenches 332 to extend downward to the first insulating layer 310. In some embodiments, the depth D1 of the trenches 332 may be in a range between 3 μm and 7 μm.

The first semiconductor devices 410 (alternatively referred to as first dies) are bonded to the first redistribution layer 320 of the first redistribution structure 300 through first connector structures 340a, while the second semiconductor device 420 (alternatively referred to as second dies) is bonded to the first redistribution layer 320 of the first redistribution structure 300 through second connector structures 340b. In some embodiments, the first semiconductor devices 410 and the second semiconductor device 420 may include dynamic random access memory (DRAM) dies, static random access memory (SRAM) dies, high bandwidth memory (HBM) dies, hybrid memory cube (HMC) dies, central processing unit (CPU) dies, graphics processing unit (GPU) dies, system-on-a-chip (SoC) unit dies, power management integrated circuit (PMIC) dies, radio frequency (RF) dies, sensor dies, micro-electro-mechanical-system (MEMS) dies, signal processing dies (such as digital signal processor, DSP) etc., the present disclosure is not limited thereto.

The first connector structures 340a and the second connector structures 340b are embedded in the second insulating layer 330, and are respectively located within the first via holes 334a and the second via holes 334b. In some embodiments, the first connector structures 340a and the second connector structures 340b are micro bump structures, wherein each of the first connector structures 340a includes a metal pillar 342a with solder 344a disposed thereon, while each of the second connector structures 340b includes a metal pillar 342b with solder 344b disposed thereon. In other embodiments, the first connector structures 340a and the second connector structures 340b may be other types of conductive connectors, such as ball grid array (BGA) connectors, metal pillars, controlled collapse chip connection (C4) bumps, electroless nickel-electroless palladium-immersion gold (ENEPIG) formed bumps, or the like. In some embodiments, an under-ball metallurgy (UBM) pattern may be included beneath the first connector structures 340a and the second connector structures 340b.

In the present embodiment, each of the first semiconductor devices 410 corresponds to one or more alignment marks AM. By using these alignment marks AM, the corresponding first semiconductor devices 410 may be accurately positioned to check for any misalignment in various directions. To enhance positioning precision, each alignment mark AM is placed close to its corresponding first semiconductor device 410. For instance, the distance X2 between each alignment mark AM and its corresponding first semiconductor device 410 is within the range of 10 μm to 1000 μm.

The trenches 332 are laterally located between the alignment marks AM and the first semiconductor devices 410. The distance X1 between each trench 332 and its corresponding first semiconductor devices 410 is less than the distance X2 between each alignment mark AM and its corresponding first semiconductor device 410.

The trenches 332 are designed to accommodate the flux used in the bonding process of the first semiconductor devices 410 and the second semiconductor device 420, and the flux may optionally be removed afterward through a cleaning process. Typically, the flux is applied to the designated bonding locations on the first redistribution structure 300 where the first semiconductor devices 410 and the second semiconductor device 420 will be joined. To prevent the flux from obscuring the alignment marks AM, the flux is not applied directly over the alignment marks AM. However, due to the fluid nature of the flux, it may flow from the bonding locations toward the alignment marks AM. The trenches 332 are strategically placed between the first semiconductor devices 410 and the alignment marks AM to capture any flux that flows toward the first alignment marks AM, preventing them from being covered by the flux.

The underfill layer 510 is located between the first redistribution structure 300 and the first semiconductor devices 410 and between the first redistribution structure 300 and the second semiconductor device 420. The underfill layer 510 surrounds the first connector structures 340a and the second connector structures 340b. The material of the underfill layer 510 may be any suitable material, such as a polymer, epoxy, molding underfill, or the like.

A portion of the underfill layer 510 is filled in the trenches 332. In this embodiment, the trenches 332 are entirely filled with the underfill layer 510; however, this disclosure is not limited thereto. In other embodiments, the underfill layer 510 may only partially fill the trenches 332, or it may not fill the trenches 332 at all.

The second encapsulation layer 520 laterally encapsulates the first semiconductor devices 410, the second semiconductor device 420 and the underfill layer 510. The second encapsulation layer 520, for example, is a molding compound made of a polymeric material (such as epoxy resins, phenolic resins, silicon-containing resins, or other suitable resins), a dielectric material having low permittivity (Dk) and low loss tangent (Df) properties, or other suitable materials. Depending on the frequency range of the high-speed applications, the material for the second encapsulation layer 520 may be selected based on the specific electrical requirements of the package structure 10A. In some embodiments, the second encapsulation layer 520 may also include inorganic fillers or compounds (e.g., silica, clay, etc.) as additives to optimize its coefficient of thermal expansion (CTE). Additionally, the material of the second encapsulation layer 520 may differ from that of the underfill layer 510.

In this embodiment, the second encapsulation layer 520 is polished to expose the top surfaces of the first semiconductor devices 410 and the second semiconductor device 420, resulting in a coplanar surface comprising the top surfaces of the second encapsulation layer 520, the first semiconductor devices 410, and the second semiconductor device 420. However, this disclosure is not limited thereto. In other embodiments, the second encapsulation layer 520 may cover the top surfaces of the first semiconductor devices 410 and the second semiconductor device 420. In some embodiments, additional thermal dissipation structures may be placed on the exposed top surface of the first semiconductor devices 410 and the second semiconductor device 420.

The second redistribution structure 600 includes a third insulating layer 610, a second redistribution layer 620 and a fourth insulating layer 630. The third insulating layer 610 is located under the interconnect die 100, the first encapsulation layer 210 and the TIVs 220. The second redistribution layer 620 is located on the third insulating layer 610. The fourth insulating layer 630 is located on the second redistribution layer 620 and the third insulating layer 610, and the second redistribution layer 620 is located between the third insulating layer 610 and the fourth insulating layer 630. The number of redistribution layers and insulating layers in the second redistribution structure 600, as shown in FIG. 1, are not used to limit the scope of the present disclosure. In other embodiments, the second redistribution structure 600 may include additional redistribution layers and insulating layers as needed.

In some embodiments, the second redistribution layer 620 includes wiring portions located on the bottom surface of the third insulating layer 610 and via portions embedded within the third insulating layer 610. The via portions of the second redistribution layer 620 are connected with the TIVs 220 and the TSVs 114 of the interconnect die 100.

Conductive elements 642 are formed on the second redistribution layer 620 and are electrically connected to it through the under-ball metallurgy (UBM) patterns 644. The conductive elements 642 may be placed on the UBM patterns 644 using a ball placement process and a reflow process. In some embodiments, the conductive elements 642 are controlled collapse chip connection (C4) bumps, ball grid array (BGA) balls, or the like. The conductive elements 642 may be used to bond to an additional electrical component, which may be a semiconductor substrate, a package substrate, a printed circuit board (PCB), or the like.

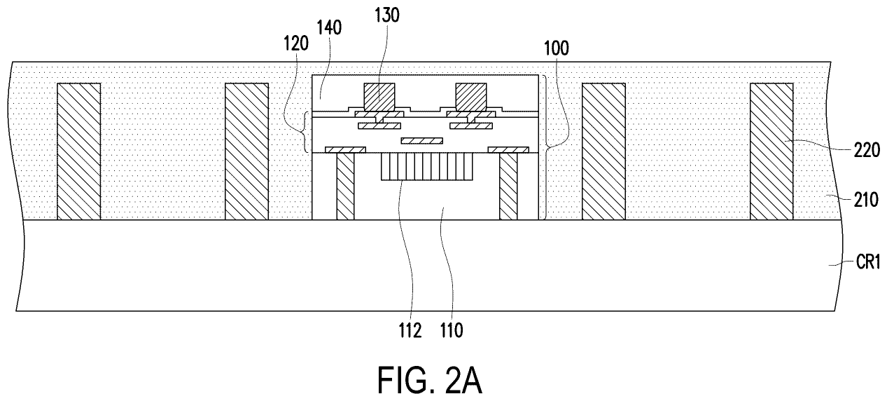

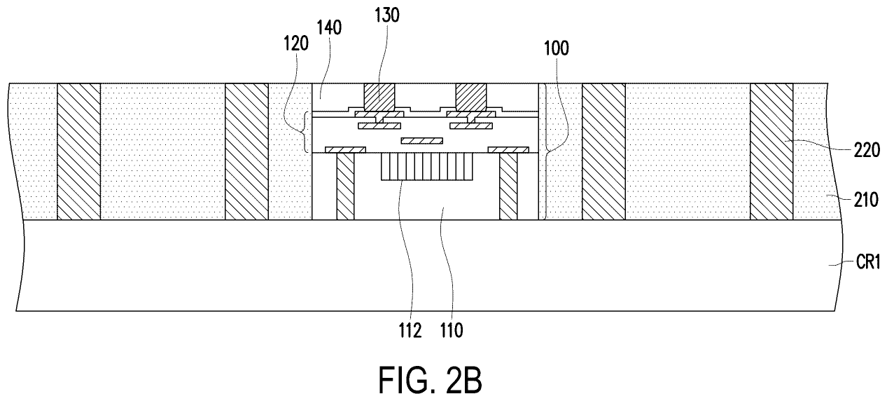

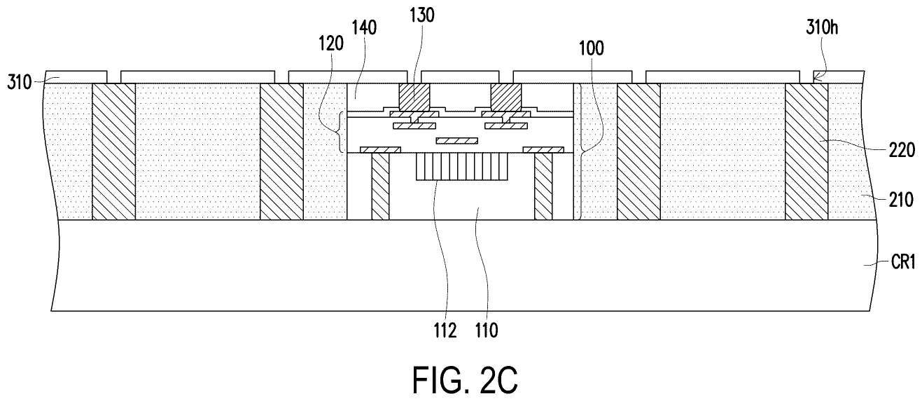

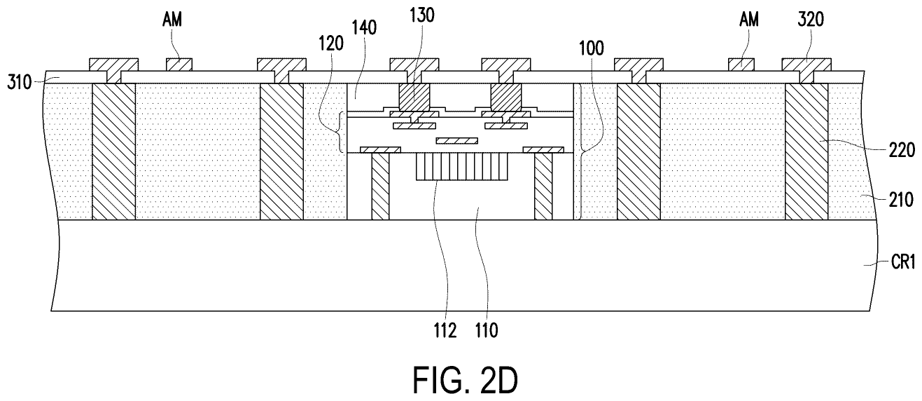

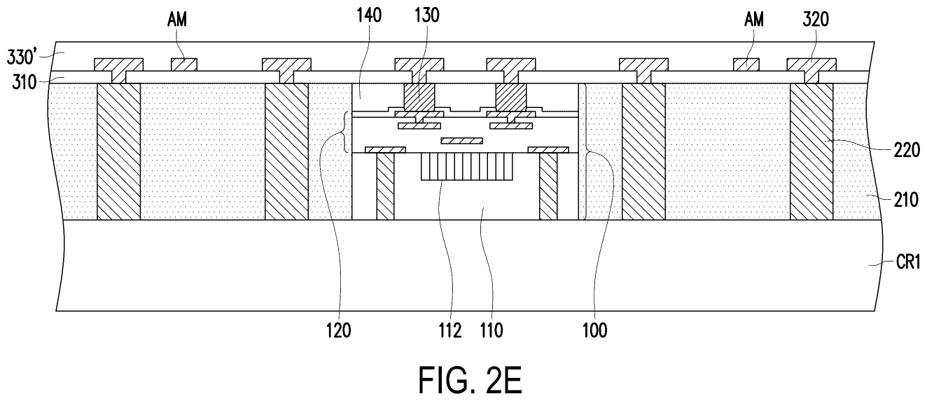

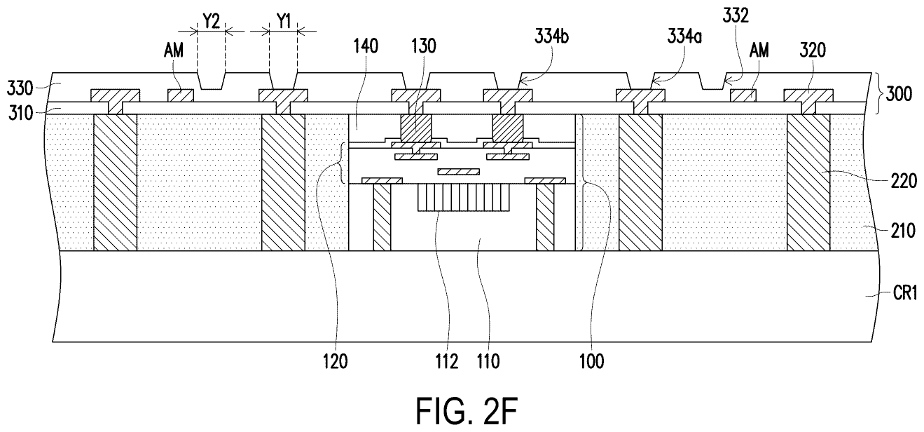

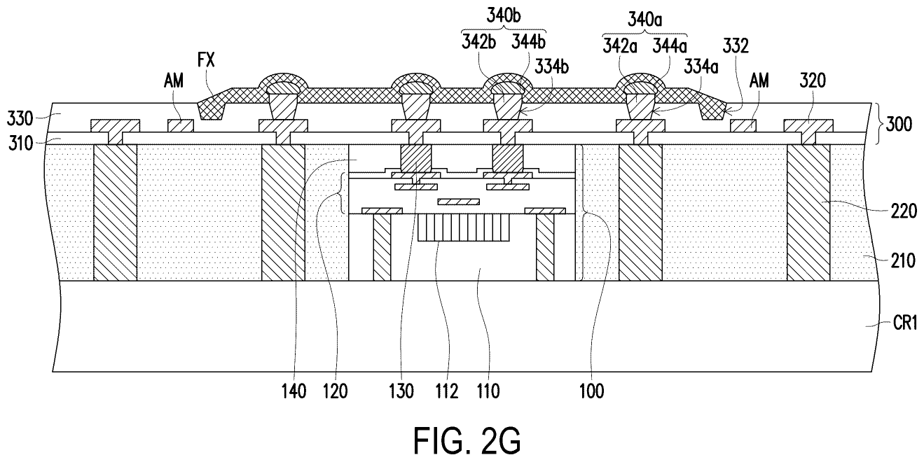

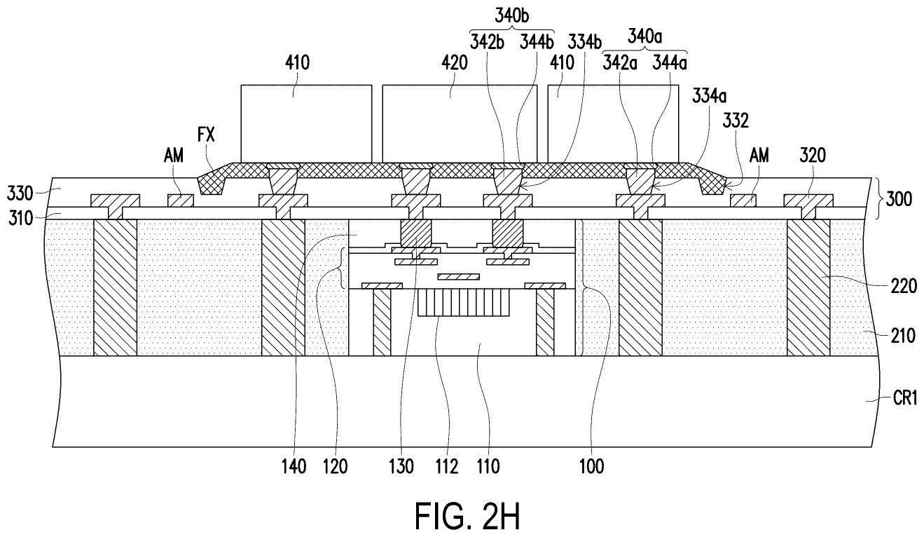

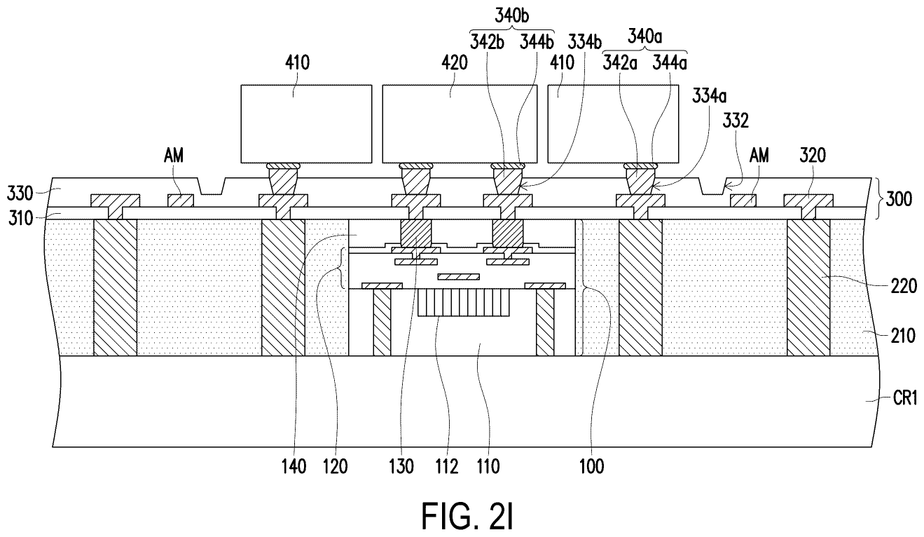

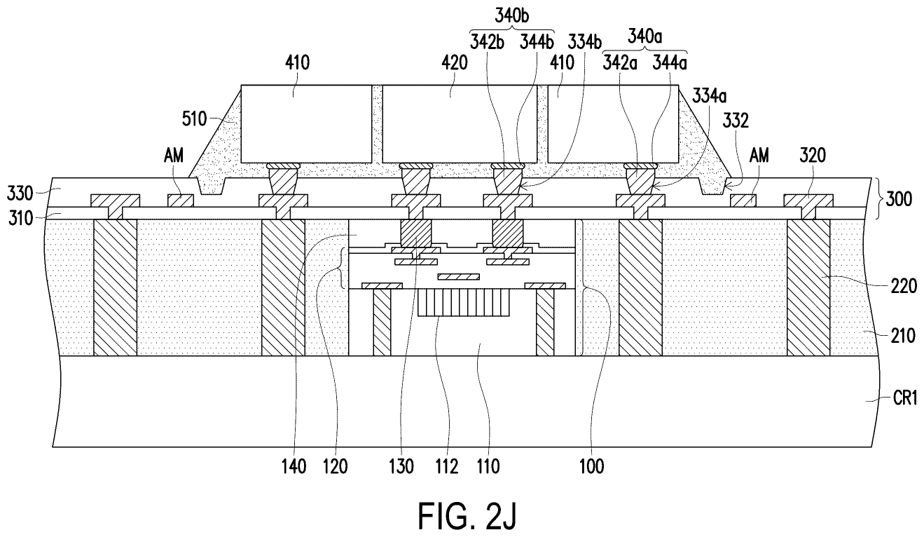

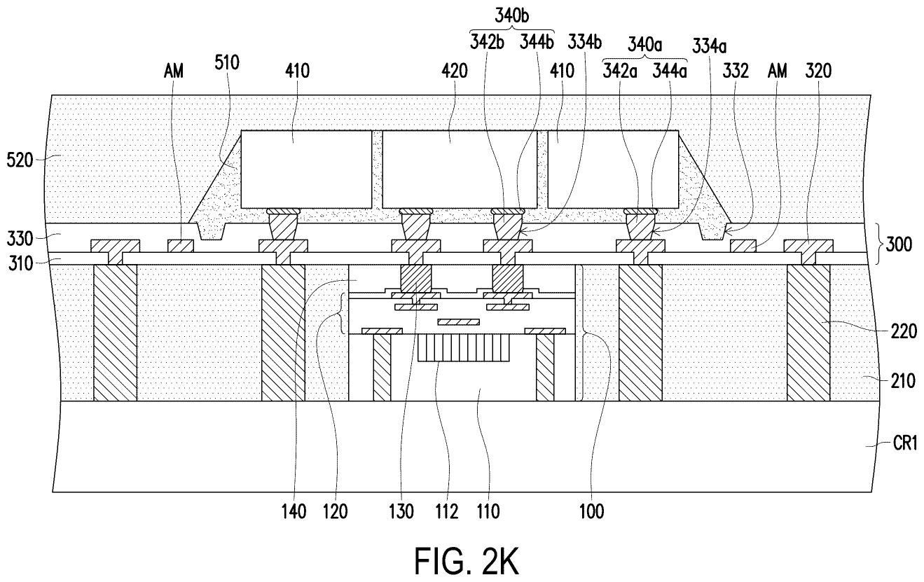

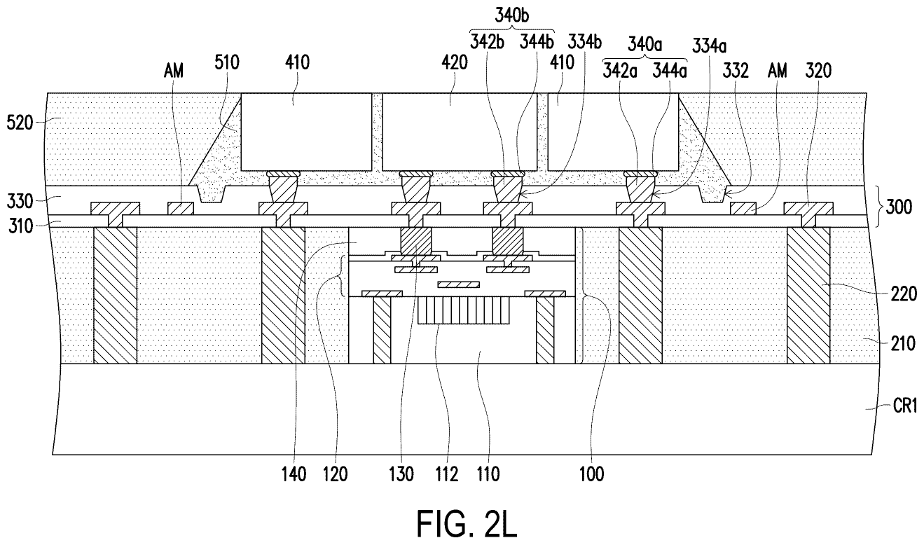

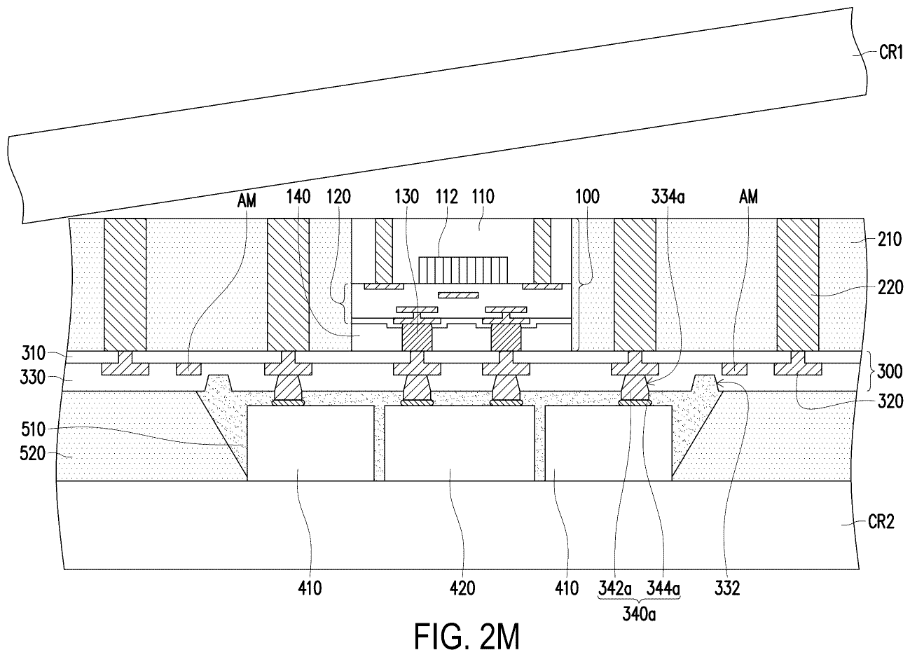

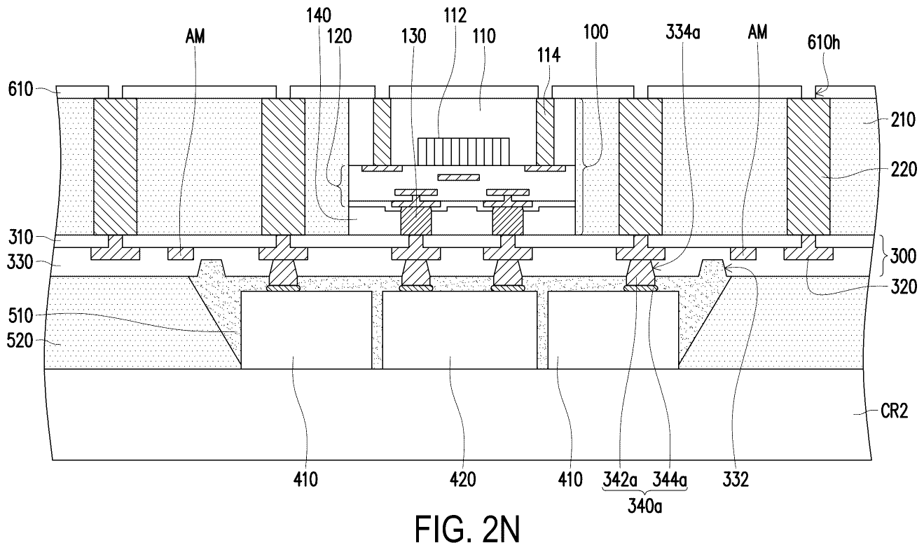

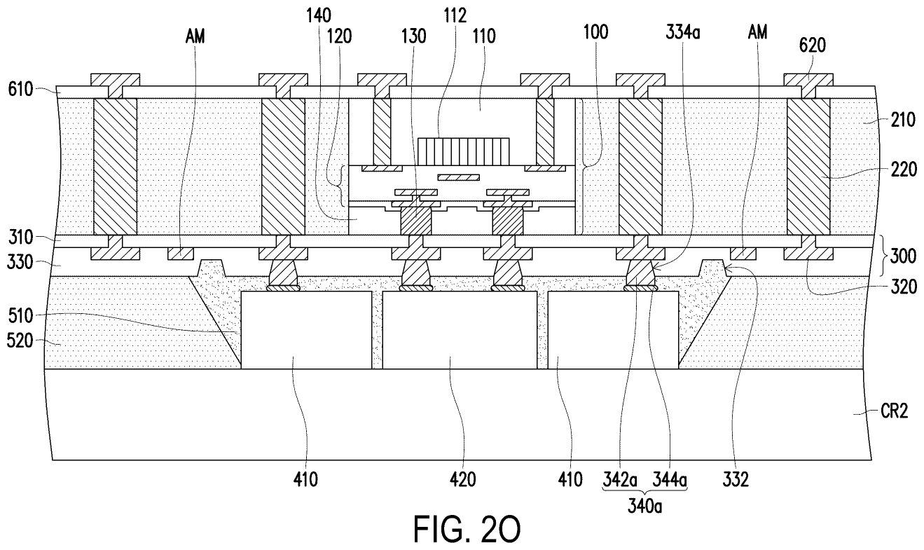

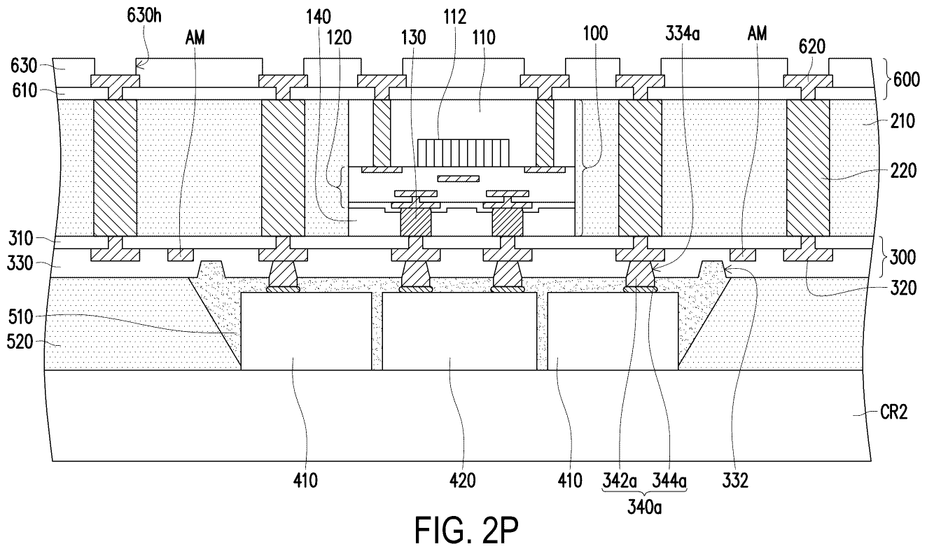

FIG. 2A to FIG. 2P are cross-sectional views illustrating a fabrication method of the package structure 10A. Referring to FIG. 2A, the TIVs 220 are formed over a first carrier CR1. In some embodiments, the formation of the TIVs 220 includes forming a patterned photoresist layer (not shown) with openings on a seed layer (not shown), where portions of the seed layer are exposed by the openings in the patterned photoresist layer. A conductive material is then deposited or plated within the openings of the patterned photoresist layer. Subsequently, the patterned photoresist layer and the excess seed layer are removed, leaving the remaining conductive structures as the TIVs 220. In some embodiments, the material of the TIVs 220 may include a metal material such as copper or copper alloys, or the like.

The interconnect die 100 is adhered to the first carrier CR1 using a die attach film (not shown). In some embodiments, the die attach film is applied to the backside surface of the interconnect die 100, and then the interconnect die 100 is attached to the first carrier CR1 with the die attach film positioned between them.

The first encapsulation layer 210 is formed to laterally wrap the TIVs 220 and the interconnect die 100. After formation, the first encapsulation layer 210 laterally encapsulates the interconnect die 100 and the TIVs 220 and is formed over the first carrier CR1, such that the interconnect die 100 is buried and/or covered.

Referring to FIG. 2B, a planarization process is then performed on the first encapsulation layer 210 to remove a portion of it, exposing the top surfaces of the TIVs 220 and the conductive bumps 130 of the interconnect die 100. In some embodiments, the top surfaces of the TIVs 220, the conductive bumps 130, the protective layer 140, and the first encapsulation layer 210 are substantially coplanar after the planarization process. The planarization process may be, for example, a chemical-mechanical polishing (CMP) process, a grinding process, or similar. In some embodiments, the planarization process may be omitted, for instance, if the TIVs 220 and the conductive bumps 130 are already exposed.

In this embodiment, prior to the planarization process, the top surfaces of the conductive bumps 130 are covered by the protective layer 140. However, the disclosure is not limited thereto. In other embodiments, the top surfaces of the conductive bumps 130 may already be exposed before placing the interconnect die 100 on the first carrier CR1.

Referring to FIG. 2C, the first insulating layer 310 is formed on the first encapsulation layer 210, the interconnect die 100 and the TIVs 220. In some embodiments, the first insulating layer 310 comprises a photoresist material, and multiple openings 310h exposing the TIVs 220 and the conductive bumps 130 are formed in the first insulating layer 310 through an exposure process and a development process. In other embodiments, the first insulating layer 310 comprises other insulating materials, and the method for forming the openings 310h includes an etching process.

Referring to FIG. 2D, the first redistribution layer 320 and the alignment marks AM are formed above the first insulating layer 310. The via portion of the first redistribution layer 320 is formed in the openings 310h of the first insulating layer 310 and connects to the TIVs 220 and the conductive bumps 130. In some embodiments, the first redistribution layer 320 and the alignment marks AM may be formed by electroplating or deposition.

Referring to FIGS. 2E and 2F, the second insulating layer 330 is formed above the first redistribution layer 320 and the alignment marks AM. The second insulating layer 330 includes the trenches 332, the first via holes 334a, and the second via holes 334b. The first redistribution layer 320 is exposed through the first via holes 334a and the second via holes 334b, with the trenches 332 laterally positioned between the alignment marks AM and the first via holes 334a. In some embodiments, a width Y1 of the first via holes 334a and the second via holes 334b may be the same of or different from a width Y2 of the trenches 332.

In some embodiments, the second insulating layer 330 comprises a photoresist material, and the method for forming the second insulating layer 330 include applying a photoresist layer 330′ over the first insulating layer 310, the first redistribution layer 320, and the alignment marks AM; exposing the photoresist layer using a mask (not shown); and developing the exposed photoresist layer 330′ to obtain the second insulating layer 330.

Referring to FIG. 2G, first connector structures 340a and the second connector structures 340b are respectively formed in the first via holes 334a and the second via holes 334b.

A flux layer FX is formed on the second insulating layer 330, as well as on the first connector structures 340a and the second connector structures 340b. For example, the fluid flux layer FX is applied to the areas on the second insulating layer 330 that include the first connector structures 340a and the second connector structures 340b, using methods such as spraying, printing, or other suitable techniques. During or after the applying of the flux layer FX, the flux layer FX may flow outward, with a portion of it flowing into at least one of the trenches 332.

In some embodiments, the material of the flux layer FX includes polyethylene glycol ether, alcohol, activators, and conductive particles. Examples of conductive particles include silver, tin, copper, or alloys thereof, as well as other conductive materials.

Referring to FIG. 2H, the first semiconductor devices 410 and the second semiconductor device 420 are attached to the first redistribution structure 300 via the flux layer FX. Subsequently, a reflow process is performed to respectively bond the first semiconductor devices 410 and the second semiconductor device 420 to the first connector structure 340a and the second connector structure 340b. In some embodiments, due to the adhesive nature of the flux layer FX, the first semiconductor devices 410 and the second semiconductor device 420 may be temporarily secured to the first redistribution structure 300 by the flux layer FX prior to the reflow process. Additionally, in some embodiments, the flux layer FX helps to reduce the temperature required for the reflow process and improves the bonding yield of the first semiconductor devices 410 and the second semiconductor device 420.

After placing the first semiconductor devices 410 onto the first redistribution structure 300, an alignment process is performed based on the alignment marks AM. For example, optical analysis may be used to detect the alignment marks AM by illuminating them with light (such as white light or light with specific wavelengths) and analyzing the resulting images. The position of the alignment marks AM is determined by pixel-based analysis to verify whether the first semiconductor devices 410 are correctly aligned.

Referring to FIG. 2I, a cleaning process is carried out to remove the flux layer FX. For instance, chemical cleaning methods may be employed for this purpose. The cleaning solution used in the cleaning process may consist of isopropanol, deionized water, or specialized flux removers, and may include either acidic solutions (such as hydrochloric acid or nitric acid) or alkaline solutions.

Referring to FIG. 2J, the underfill layer 510 is formed between the second insulating layer 330 and the first semiconductor devices 410 and between the second insulating layer 330 and the second semiconductor device 420. Specifically, the underfill layer 510 is formed around the first connector structure 340a and the second connector structure 340b.

In this embodiment, the flux layer FX is removed from the trenches 332 before the formation of the underfill layer 510. As a result, the underfill layer 510 may be deposited into the trenches 332. In some embodiments, the entire or partial volume of the trenches 332 is filled with the underfill layer 510. In other embodiments, the underfill layer 510 does not flow into the trenches 332, leaving them unfilled.

Referring to FIG. 2K, the second encapsulation layer 520 is formed to laterally wrap the first semiconductor devices 410 and the second semiconductor device 420. After formation, the second encapsulation layer 520 laterally encapsulates the first semiconductor devices 410 and the second semiconductor device 420 and is formed over the first redistribution structure 300, such that the first semiconductor devices 410 and the second semiconductor device 420 are buried and/or covered.

Referring to FIG. 2L, a planarization process is then performed on the second encapsulation layer 520 to remove a portion of it, exposing the top surfaces of the first semiconductor devices 410 and the second semiconductor device 420. In some embodiments, the top surfaces of the first semiconductor devices 410, the second semiconductor device 420 and the second encapsulation layer 520 are substantially coplanar after the planarization process. The planarization process may be, for example, a chemical-mechanical polishing (CMP) process, a grinding process, or similar. In some embodiments, the planarization process may be omitted.

Referring to FIG. 2M, the structure shown in FIG. 2L is rotated and placed onto a second carrier CR2. The first carrier CR1 is then removed. In some embodiments, after removing the first carrier CR1, the top surface of the structure undergoes polishing, such as CMP.

Referring to FIG. 2N, the third insulating layer 610 is formed on the first encapsulation layer 210, the interconnect die 100 and the TIVs 220. In some embodiments, the third insulating layer 610 comprises a photoresist material, and multiple openings 610h exposing the TIVs 220 and the TSVs 114 are formed in the third insulating layer 610 through an exposure process and a development process. In other embodiments, the third insulating layer 610 comprises other insulating materials, and the method for forming the openings 610h includes an etching process.

Referring to FIG. 2O, the second redistribution layer 620 is formed above the third insulating layer 610. The via portion of the second redistribution layer 620 is formed in the openings 610h of the third insulating layer 610 and connects to the TIVs 220 and the TSVs 114. In some embodiments, the second redistribution layer 620 may be formed by electroplating or deposition.

Referring to FIG. 2P, the fourth insulating layer 630 is formed above the second redistribution layer 620. The fourth insulating layer 630 includes the third via holes 630h. The second redistribution layer 620 is exposed through the third via holes 630h.

After completing the process shown in FIG. 2P, the UBM patterns 644 are formed within the third via holes 630h of the fourth insulating layer 630, as shown in FIG. 1. Subsequently, the conductive elements 642 are formed on the UBM patterns 644.

In some embodiments, a singulation process is performed before or after the formation of the conductive elements 642 to separate the package structures from the bulk structure. For example, prior to the singulation process, multiple package structures are formed together and connected with each other. After the singulation process, these package structures are individually separated from one another.

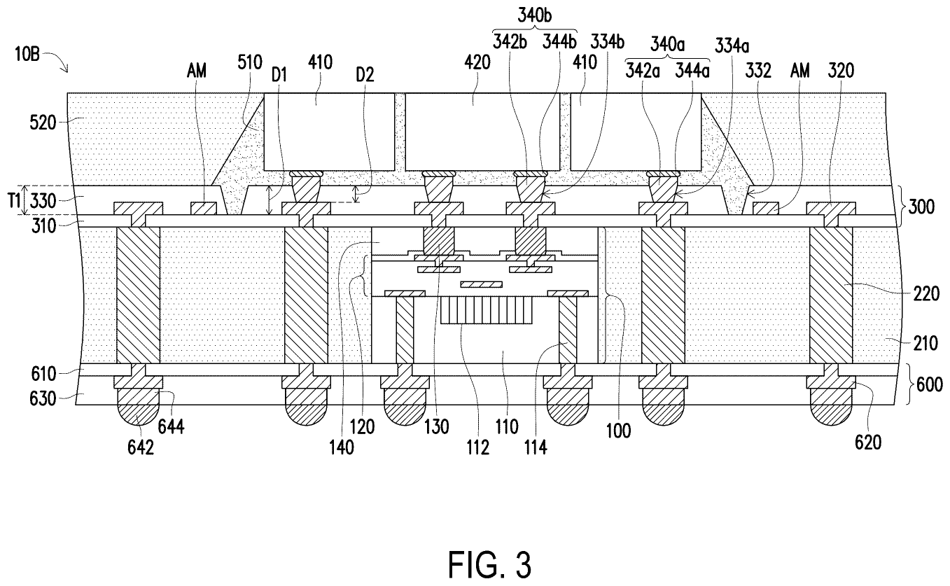

FIG. 3 is a cross-sectional view illustrating a package structure 10B in accordance with some embodiments of the present disclosure. The package structure 10B in FIG. 3 is similar to the package structure 10A in FIG. 1. For details regarding the corresponding parts, please refer to the previous description, as they will not be reiterated here. The differences between the package structure 10B in FIG. 3 and the package structure 10A in FIG. 1 include the following: in the package structure 10B in FIG. 3, the depth D1 of the trenches 332 is greater than the depths D2 of the first via holes 334a and second via holes 334b. In this embodiment, the depth D1 is approximately equal to the thickness T1 of the second insulating layer 330, causing the depth D1 to extend into the first insulating layer 310.

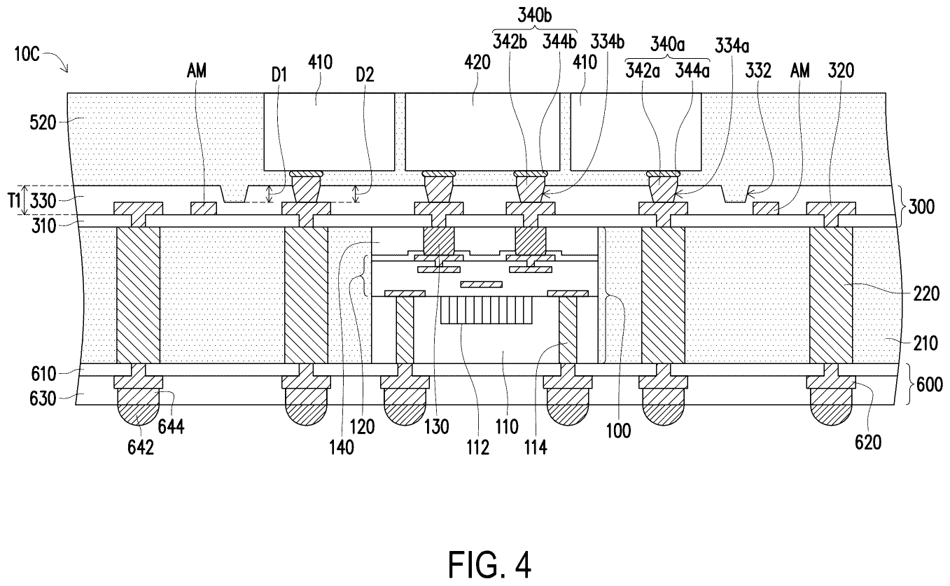

FIG. 4 is a cross-sectional view illustrating a package structure 10C in accordance with some embodiments of the present disclosure. The package structure 10C in FIG. 4 is similar to the package structure 10A in FIG. 1. For details regarding the corresponding parts, please refer to the previous description, as they will not be reiterated here. The differences between the package structure 10C in FIG. 4 and the package structure 10A in FIG. 1 include the following: in the package structure 10C in FIG. 4, the second encapsulation layer 520 is used as the underfill layer, and the second encapsulation layer 520 fills the space between the first redistribution structure 300 and the first semiconductor devices 410 and the space between the first redistribution structure 300 and the second semiconductor device 420. In this embodiment, the trenches 332 is filled by the second encapsulation layer 520.

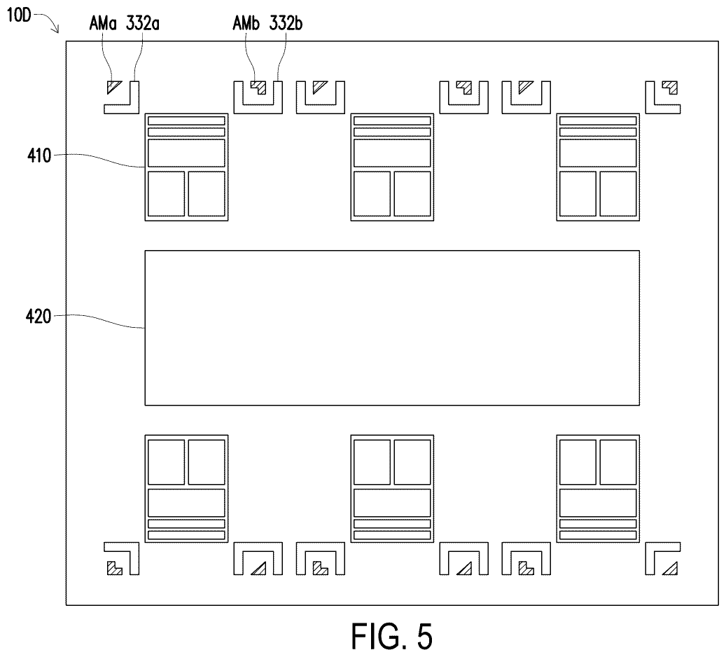

FIG. 5 is a perspective top view illustrating a package structure 10D in accordance with some embodiments of the present disclosure. The package structure 10D in FIG. 5 is similar to the package structure 10A in FIG. 1. For details regarding the corresponding parts, please refer to the previous description, as they will not be reiterated here. Referring to FIG. 5, the first redistribution structure includes first alignment marks AMa and second alignment marks AMb. The first alignment marks AMa and the second alignment marks AMb, for example, may have different shapes to facilitate distinguishing their relative positions to the first semiconductor devices 410. In this embodiment, each first semiconductor device 410 corresponds to one first alignment mark AMa and one second alignment mark AMb. Additionally, in this embodiment, the uppermost insulating layer in the first redistribution structure (e.g., the second insulating layer) includes first trenches 332a and second trenches 332b, which also have different shapes. For instance, the first trenches 332a near the corners of the package structure 10D are approximately L-shaped, while the second trenches 332b, positioned horizontally between two first semiconductor devices 410, have a right-angled U-shape. This design is intentional, as the flux tends to flow from the location intended for the first semiconductor devices 410 towards the alignment marks. Therefore, the trenches are only required near the side of the alignment marks facing the first semiconductor devices 410, while the side of the alignment marks facing away from the first semiconductor devices 410 does not require trenches.

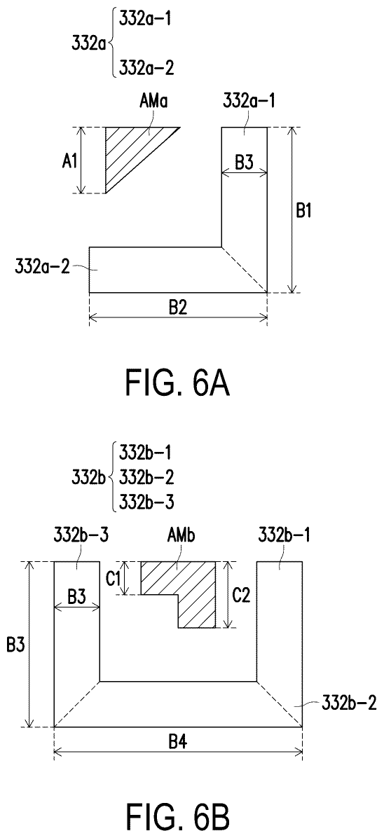

Referring to FIG. 6A, the width A1 of the first alignment marks AMa is in a range between 20 μm and 40 μm, and the width B3 of the first trench 332a is also in a range between 20 μm and 40 μm. The first trench 332a may consist of a first section 332a-1 and a second section 332a-2, with the first section 332a-1 connected to the second section 332a-2. The extending direction of the first section 332a-1 is approximately perpendicular to the extending direction of the second section 332a-2. The length B1 of the first section 332a-1 and the length B2 of the second section 332a-2 are each within a range of 130 μm to 150 μm.

Referring to FIG. 6B, the length C2 of the second alignment marks AMb ranges from 20 μm to 40 μm, while the width C1 of the second alignment marks AMb is less than or equal to the length C2. When the width C1 is equal to the length C2, the second alignment marks AMb, for example, take on a rectangular shape. The second trench 332b consists of a first section 332b-1, a second section 332b-2, and a third section 332b-3 that are sequentially connected. The extending directions of the first section 332b-1 and the third section 332b-3 differ from the extending direction of the second section 332b-2. For instance, the extending directions of the first section 332b-1 and the third section 332b-3 are perpendicular to the extending direction of the second section 332b-2. The length B3 of the first section 332b-1 and the third section 332b-3 and the length B4 of the second section 332b-2 are each within a range of 130 μm to 150 μm.

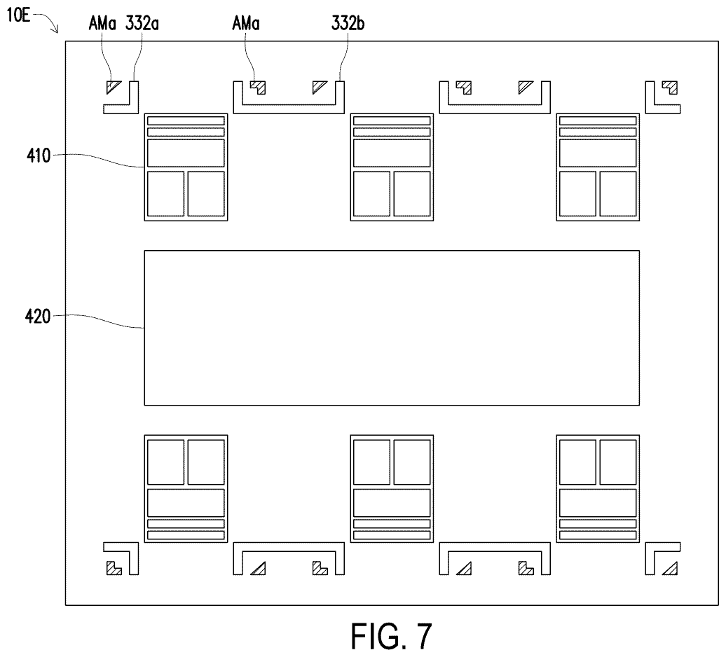

The second alignment mark AMb and/or the first alignment mark AMa is/are laterally positioned between the first section 332b-1 and the third section 332b-3. When both the second alignment mark AMb and the first alignment mark AMa are placed between the first section 332b-1 and the third section 332b-3 of one second trench 332b, the configuration can be referenced in the second trench 332b of the package structure 10E shown in FIG. 7.

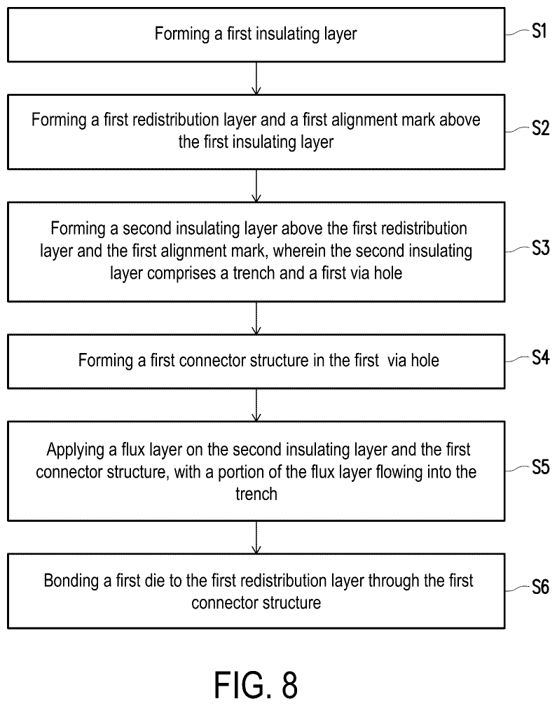

FIG. 8 is a flow chart of a fabrication method of the package structure in accordance with some embodiments of the present disclosure. Referring to FIG. 8, in the step S1, a first insulating layer is formed. The first insulating layer may be formed over various packaging components, such as the encapsulation layer, substrate core, and/or others. For instance, the step S1 in FIG. 8 corresponds to the process shown in FIG. 2C.

In the step S2, a first redistribution layer and a first alignment mark are formed above the first insulating layer. In some embodiments, various shapes of the alignment marks may be formed simultaneously, such as the first alignment mark AMa shown in FIG. 6A and the second alignment mark AMb shown in FIG. 6B. The step S2 in FIG. 8 corresponds to the process shown in FIG. 2D.

In the step S3, a second insulating layer is formed above the first redistribution layer and the first alignment mark. The second insulating layer comprises a trench and a first via hole. In some embodiments, various shapes of the trenches may be formed simultaneously, such as the first trench 332a shown in FIG. 6A and the second trench 332b shown in FIG. 6B. In some embodiments, the second insulating layer further comprises a second via hole. The step S3 in FIG. 8 corresponds to the process shown in FIG. 2E and FIG. 2F.

In the step S4, a first connector structure is formed within the first via hole. In some embodiments, the formation of the first connector structure is accompanied by the formation of a second connector structure within the second via hole. In the step S5, a flux layer is applied onto the second insulating layer and the first connector structure. In some embodiments, the flux layer is also applied onto the second connector structure. A portion of the flux layer flows into the trench. The steps S4 and S5 in FIG. 8 correspond to the process shown in FIG. 2G.

In the step S6, a first die is bonded to the first redistribution layer through the first connector structure. In some embodiments, a second die is bonded to the first redistribution layer through the second connector structure. The step S6 in FIG. 8 correspond to the process shown in FIG. 2I.

Accordingly, in some embodiments, the present disclosure relates to a package structure including a redistribution structure and a first semiconductor device. The redistribution structure includes a first insulating layer, a second insulating layer, a first redistribution layer and a first alignment mark. The first redistribution layer and the first alignment mark are located between the first insulating layer and the second insulating layer. The first semiconductor device is bonded to the redistribution structure through a first connector structure. The second insulating layer includes a fiducial mark trench laterally located between the first alignment mark and the first connector. The fiducial mark trench is not overlapping with the first redistribution layer and the first alignment mark in a vertical direction.

In other embodiments, the present disclosure relates to a package structure including a redistribution structure, a die and an underfill layer. The redistribution structure includes a first insulating layer, a second insulating layer, a first redistribution layer and a first alignment mark. The first redistribution layer and the first alignment mark are located between the first insulating layer and the second insulating layer. The die is attached to the redistribution structure. The second insulating layer includes a trench laterally located between the first alignment mark and the die. The underfill layer is located between the redistribution structure and the die. A portion of the underfill layer is filled in the trench.

In yet other embodiments, the present disclosure relates to a fabrication method of a package structure including the following steps. A first insulating layer is formed. A first redistribution layer and a first alignment mark are formed above the first insulating layer. A second insulating layer is formed above the first redistribution layer and the first alignment mark. The second insulating layer includes a trench and a first via hole. The first redistribution layer is exposed by the first via hole, and the trench is laterally located between the first alignment mark and the first via hole. A first connector structure is formed in the first via hole. A flux layer is applied above the second insulating layer and the first connector structure, with a portion of the flux layer flowing into the trench. A first die is bonded to the first connector structure.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a redistribution structure, comprising:
a first insulating layer and a second insulating layer; and
a first redistribution layer and a first alignment mark, located between the first insulating layer and the second insulating layer; and
a first semiconductor device, bonded to the redistribution structure through a first connector structure, wherein the second insulating layer comprises a fiducial mark trench laterally located between the first alignment mark and the first connector, wherein the fiducial mark trench is not overlapping with the first redistribution layer and the first alignment mark in a vertical direction.

2. The package structure of claim 1 further comprises:
an underfill layer, surrounding the first connector, and a portion of the underfill layer is filled in the fiducial mark trench.

3. The package structure of claim 2 further comprises:
a second semiconductor device, bonded to the redistribution structure through a second connector, wherein the underfill layer surrounds the first connector and the second connector; and
an encapsulation layer, encapsulating the first semiconductor device, the second semiconductor device and the underfill layer.

4. The package structure of claim 1 wherein the fiducial mark trench has a right-angled U-shape.

5. The package structure of claim 1 wherein a depth of the fiducial mark trench is in a range between 3 μm and 7 μm.

6. A package structure, comprising:
a redistribution structure, comprising:
a first insulating layer and a second insulating layer; and
a first redistribution layer and a first alignment mark, located between the first insulating layer and the second insulating layer; and
a die, attached to the redistribution structure, wherein the second insulating layer comprises a trench laterally located between the first alignment mark and the die; and
an underfill layer, located between the redistribution structure and the die, wherein a portion of the underfill layer is filled in the trench.

7. The package structure of claim 6 further comprises:
a micro bump structure, embedded in the second insulating layer and electrically connected with the first redistribution layer, wherein the underfill layer surrounds the micro bump structure, and the die is bonded to the redistribution structure through the micro bump structure.

8. The package structure of claim 7 wherein the trench is laterally located between the micro bump structure and the first alignment mark.

9. The package structure of claim 6 wherein the trench comprises a first section, a second section, and a third section that are sequentially connected, wherein extending directions of the first section and the third section differ from an extending direction of the second section, and the first alignment mark is laterally located between the first section and the third section.

10. The package structure of claim 9 wherein the redistribution structure comprises:
a second alignment mark, located between the first insulating layer and the second insulating layer, wherein the first alignment mark and the second alignment mark are laterally located between the first section and the third section.

11. The package structure of claim 6 wherein a width of the trench is in a range between 20 μm and 40 μm.

12. The package structure of claim 6 wherein a depth of the trench is less than a thickness of the second insulating layer.

13. A fabrication method of a package structure, comprising:
forming a first insulating layer;
forming a first redistribution layer and a first alignment mark above the first insulating layer;
forming a second insulating layer above the first redistribution layer and the first alignment mark, wherein the second insulating layer comprises a trench and a first via hole, wherein the first redistribution layer is exposed by the first via hole, and the trench is laterally located between the first alignment mark and the first via hole;
forming a first connector structure in the first via hole;
applying a flux layer above the second insulating layer and the first connector structure, with a portion of the flux layer flowing into the trench; and
bonding a first die to the first connector structure.

14. The fabrication method of claim 13, further comprises:
performing a cleaning process to remove the flux layer; and
forming an underfill layer between the second insulating layer and the first die.

15. The fabrication method of claim 13, further comprises:
performing an alignment process of the first die based on the first alignment mark.

16. The fabrication method of claim 13, wherein a method for forming the second insulating layer comprises:
applying a photoresist layer on the first insulating layer, the first redistribution layer and the first alignment mark;
exposing the photoresist layer using a mask; and
developing the photoresist layer to obtain the second insulating layer comprising the trench and the first via hole.

17. The fabrication method of claim 13, wherein a width of the first via hole is different from a width of the trench.

18. The fabrication method of claim 13, wherein a depth of the trench is less than a thickness of the second insulating layer.

19. The fabrication method of claim 13, wherein the trench comprises a first section, a second section, and a third section that are sequentially connected, wherein extending directions of the first section and the third section differ from an extending direction of the second section, and the first alignment mark is laterally located between the first section and the third section.

20. The fabrication method of claim 13, wherein a width of the trench is in a range between 20 μm and 40 μm.
